(19) United States
(12) Patent Application Publication
(10) Pub. No.: US 2007/0063771 A1
(43) Pub. Date: Mar. 22, 2007

(54) Bias-T circuit

(75) Inventors: Qi Pan, Didcot (GB); Joseph Barnard, London (GB)

Correspondence Address: SUGHRUE MION, PLLC, 2100 PENNSYLVANIA AVENUE, N.W., SUITE 800, WASHINGTON, DC, 20037, US

(73) Assignee: BOOKHAM TECHNOLOGY, PLC.

(21) Appl. No.: 11/230,639

(22) Filed: Sep. 21, 2005

(51) Int. Cl. H03F 1/26

(52) U.S. Cl. 330/149

(57) ABSTRACT

A bias-T circuit including a radio frequency signal input device and a dc bias input device connected in parallel with an output. The radio frequency signal input device includes a capacitive element in series with the output. The dc bias input device includes a radio frequency transistor for controlling the dc bias level at the output. The f_{T} value of the radio frequency transistor is at least 30 GHz, more preferably at least 50 GHz and yet more preferably at least 70 GHz.

### FIELD OF THE INVENTION

The present invention relates to a bias-T circuit.

### BACKGROUND OF THE INVENTION

Bias-T circuits are useful, for example, for providing both a radio frequency (RF) signal and DC voltage down a single transmission line to a modulator.

A basic example of a known bias-T circuit is shown in FIG. 1. The bias-T circuit comprises two inputs: a radio frequency input 102 and a DC bias input 104. The RF input 102 is connected to a DC blocking capacitor 106. The DC bias input is connected to an RF blocking inductor 108. The DC blocking capacitor 106 and the RF blocking inductor 108 are both connected to the output 110 of the bias-T circuit. The output signal is the combined RF signal and DC bias voltage.

The DC blocking capacitor 106 provides a low impedance path to the RF signal from the RF input 102 to the output 110. In addition, the RF blocking inductor 108 provides a high impedance path to the RF signal, and this prevents the RF signal from diverting into the DC bias input. However, the RF blocking inductor 108 provides a low impedance path to the DC bias voltage from the DC bias input 104 through to the output 110. The DC blocking capacitor 106 presents a high impedance to the DC bias voltage, and this prevents the DC bias voltage from entering the RF input 102, which could be damaging to the equipment supplying the RF signal.

### SUMMARY OF THE INVENTION

It has been observed that there is a problem with this conventional approach to providing a bias-T circuit in that whereas using bigger inductors or using multiple inductors can improve the impedance over a relatively wide RF frequency range, to do so is not conducive to reducing the size of the circuit and in particular is not conducive to fitting the circuit on a small printed circuit board (PCB) for, for example, a pluggable optical module.

It is an aim of the present invention to provide a new type of bias-T circuit, and in particular it is an aim of the present invention to provide a new type of bias-T circuit that can provide a good level of performance over a wide frequency range whilst at the same time being suitable for use in small devices.

According to one aspect of the present invention, there is provided a bias-T circuit including a radio frequency signal input device and a dc bias input device connected in parallel with an output: the radio frequency signal input device including a capacitive element in series with the output; and the dc bias input device including a radio frequency transistor for controlling the dc bias level at the output.

In a preferred embodiment, the f_{T} value of the radio frequency transistor is at least 30 GHz, more preferably at least 50 GHz and yet more preferably at least 70 GHz.

In one embodiment, the dc bias input device further includes at least one ferrite bead.

In one embodiment, the circuit further includes at least one operational amplifier for controlling the bias of the radio frequency transistor.

In one embodiment, the radio frequency transistor includes a base electrode connected to the output of the operational amplifier, a collector electrode connected to the output and an emitter electrode connected to a voltage supply. Preferably, the collector electrode of the radio frequency transistor is also connected to a non-inverting input of the operational amplifier to create a feedback loop.

According to another aspect of the present invention, there is provided an optical modulation system comprising: a bias-T circuit as described above; and an optical modulator connected to the output of the bias-T circuit, wherein said optical modulator is powered by the dc bias input device and modulates an optical signal on the basis of a radio frequency signal from the radio frequency signal input device.

In one embodiment, the optical modulator is connected to the output via a transmission line.

### BRIEF DESCRIPTION OF THE DRAWINGS

For a better understanding of the present invention and to show how the same may be put into effect, reference will now be made, by way of example only, to the following drawings in which:

FIG. 1 shows a basic example of a known bias-T circuit;

FIG. 2 shows an active bias-T circuit according to an embodiment of the present invention;

FIG. 3 shows a DC equivalent circuit of the active bias-T circuit of FIG. 2;

FIG. 4 shows an RF equivalent circuit of the active bias-T circuit of FIG. 2; and

FIG. 5 shows an optical modulation system comprising a bias-T circuit.

### DESCRIPTION OF PREFERRED EMBODIMENT

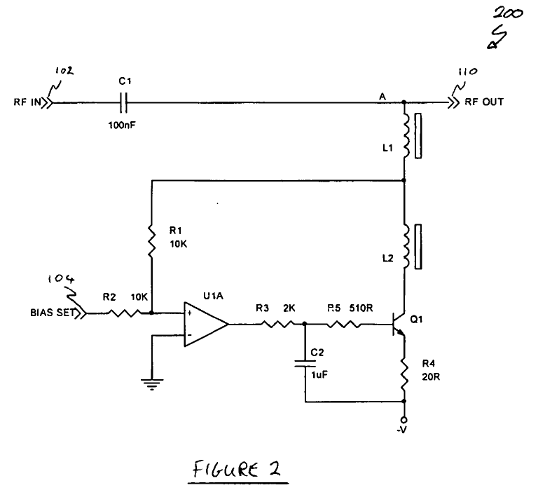

Reference is first made to FIG. 2, which shows a bias-T circuit 200 according to an embodiment of the present invention. The bias-T circuit 200 comprises an RF input 102 and a DC bias input 104 and an output 110. The RF input 102 is connected to a DC blocking capacitor C1, which performs the function of preventing the DC bias voltage from entering the RF signal source.

The circuit has two high frequency ferrite bead inductors L1 and L2 connected in series at the point labelled A, which inductors have a relatively small physical size. The inductors L1 and L2 are connected to the collector of an NPN bipolar silicon-germanium (SiGe) type high performance RF transistor Q1. The RF transistor Q1 has a transition frequency, f_{T} value of 70 GHz, wherein the f_{T} value is the theoretical frequency at which the current gain (h_{fe}) of the transistor is unity (i.e. 0 dB).

The DC bias input 104 is connected via a resistor R2 to the non-inverting input of an operational amplifier U1A. The inverting input of the op-amp U1A is connected to ground. The output of the op-amp U1A is connected to the base of transistor Q1 via two resistors R3 and R5. A resistor R1 is connected in a feedback loop from the point between the two inductors L1 and L2 to the non-inverting input of U1A.

The emitter of Q1 is connected to a resistor R4, which in turn is connected to a negative voltage −V. A capacitor C2 is connected between the negative voltage −V and the point between resistors R3 and R5.

The operation of the active bias-T circuit 200 will now be described, beginning with the setting of the DC bias voltage. The DC bias voltage is applied to the input 104, and this sets the voltage on the one side of resistor R2. Since the non-inverting and inverting inputs of the op-amp U1A must be at the same voltage, and the inverting input is fixed at ground, then the voltage at the non-inverting input is 0 V. Therefore, there is a voltage drop equal to the value of the DC bias voltage across resistor R2, and hence a current through the resistor equal to the DC bias voltage divided by the resistance of R2. Since no current flows into the input of the op-amp U1A, the current through resistor R1 must be the same as though R2, and, hence, the voltage drop across R1 is −1×DC bias voltage. Therefore, as the non-inverting input of U1A is 0 V, the voltage at the point between L1 and L2 is approximately −1×DC bias voltage. Since the inductor L1 presents a low impedance to DC, the voltage at point A and also at the DC bias output voltage is also approximately −1×DC bias input voltage.

The voltage at point A is set to this value due to the feedback loop of the operational amplifier U1A and transistor Q1, as the output of U1A will be such so as ensure that the voltage at A is maintained. It does this by setting the voltage at the base of the transistor Q1 in order to achieve the required voltage at the emitter.

Connecting the feedback to non-inverting input of U1A, as described above, has the advantage that only one operational amplifier is required.

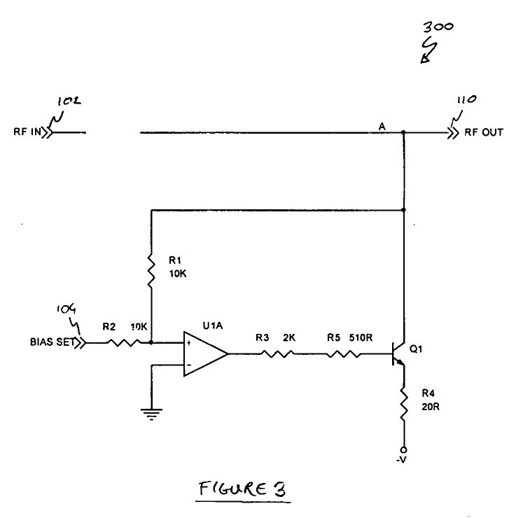

The DC equivalent circuit 300 as seen to the DC bias voltage is shown in FIG. 3. As mentioned previously, the capacitor C1 blocks the DC from entering the RF input, and hence this is shown as an open circuit in FIG. 3. The capacitor C2 from FIG. 2 also acts as an open circuit to DC, and this is therefore also not present in the DC equivalent circuit 300. The inductors L1 and L2 are shown as short-circuits to DC.

In this example, the value of the DC bias input voltage is 1.7V and the value of −V is −4V. The value of the voltage at A is therefore −1.7V, and this therefore corresponds to the value of the DC bias at the output 110.

Referring again to FIG. 2, the operation of the circuit from the point of view of the RF signal will now be considered. The RF signal is applied to the RF input 102, and the capacitor C1 presents a low impedance to the RF signal. The RF signal can then pass to the output 110.

The RF signal is separated from the DC bias input by the resistors R1 and R2. The values shown in the embodiment in FIG. 2 are 10K for both of R1 and R2. Since the transmission line over which the RF signal is to be sent in the preferred embodiment has an impedance of 50R, the combined impedance of the two resistors is significantly higher, and hence the impedance to the RF signal is sufficiently high. In addition, the input to the operational amplifier U1A is of a high impedance and the RF signal is therefore not affected by being connected to U1A.

The RF signal is separated from the voltage supply −V by the RF transistor Q1. The RF transistor provides a good level of impedance to the RF signal over a relatively wide frequency range from relatively low frequency signal components to relatively high frequency signal components. The ferrite bead inductors L1 and L2 provide compensatory impedance for any particularly high frequency signal components that may be present in the RF signal.

The capacitor C2 is used to bleed off RF signals that are amplified by the op-amp U1A to the negative supply voltage. C2 can also help to prevent DC loop oscillation in the circuit.

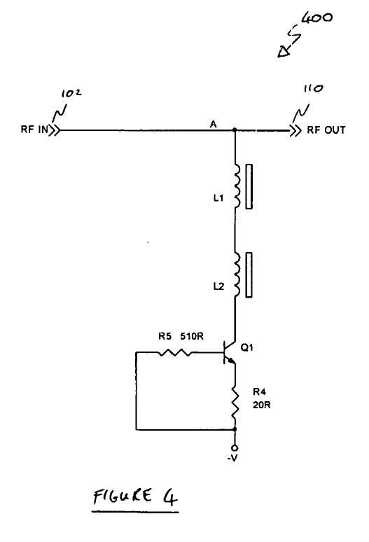

FIG. 4 shows the RF equivalent circuit 400, as seen to the RF signal. This shows the capacitor C1 acting as a short-circuit and not impeding the RF signal. As stated above, resistors R1 and R2 act as sufficiently high impedances, and this path is therefore shown open-circuit to the RF signal. Capacitor C2 is shown as providing a short-circuit path to the negative supply −V.

The relatively small physical dimensions of all the components present in the circuit, allow the circuit to be constructed on a PCB of a relatively small size.

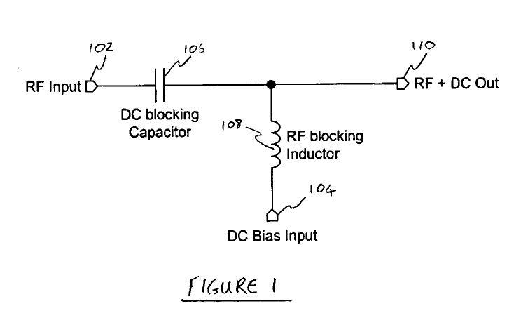

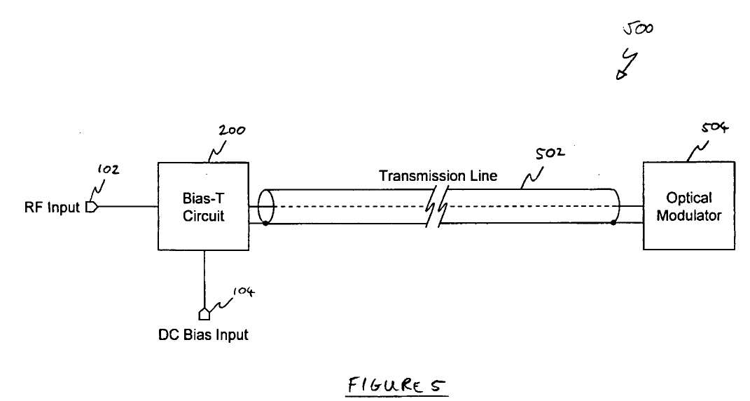

Reference is now made to FIG. 5, which shows an optical modulation system 500 comprising the active bias-T circuit of FIG. 1. The RF input 102 and DC bias input 104 are connected to the bias-T circuit 200, as described above. The combined RF and DC bias output is connected to a high speed transmission line 502. The other end of the transmission line 502 is connected to an electric-absorption optical modulator 504. The optical modulator is then driven by the DC bias voltage and modulates an optic signal on the basis of the RF signal to provide a modulated optical signal. The above-described Bias-T circuit is useful, for example, in 10 Gb/s applications, where the signal spectrum can range from roughly 10 kHz up to 10 GHz.

The Bias-T circuit described above also allows exact set-up of the DC Bias voltage without the use of a monitor.

The applicant draws attention to the fact that the present invention may include any feature or combination of features disclosed herein either implicitly or explicitly or any generalisation thereof, without limitation to the scope of any definitions set out above. In view of the foregoing description it will be evident to a person skilled in the art that various modifications may be made within the scope of the invention.

What is claimed is:

1. A bias-T circuit including a radio frequency signal input device and a dc bias input device connected in parallel with an output:
the radio frequency signal input device including a capacitive element in series with the output; and
the dc bias input device including a radio frequency transistor for controlling the dc bias level at the output.

2. A bias-T circuit as claimed in claim 1, wherein the f_{T} value of the radio frequency transistor is at least 30 GHz, more preferably at least 50 GHz and yet more preferably at least 70 GHz.

3. A bias-T circuit as claimed in claim 1, wherein the dc bias input device further includes at least one ferrite bead.

4. A bias-T circuit as claimed in claim 1, further including at least one operational amplifier for controlling the bias of the radio frequency transistor.

5. A bias-T circuit as claimed in claim 4, wherein the radio frequency transistor includes a base electrode connected to the output of the operational amplifier, a collector electrode connected to the output and an emitter electrode connected to a voltage supply.

6. A bias-T circuit according to claim 6, wherein the collector electrode of the radio frequency transistor is also connected to an input of the operational amplifier to create a feedback loop.

7. A bias-T circuit according to claim 6, wherein the collector electrode of the radio frequency transistor is connected to a non-inverting input of the operational amplifier.

8. An optical modulation system comprising:
a bias-T circuit according to claim 1; and
an optical modulator connected to the output of the bias-T circuit, wherein said optical modulator is powered by the dc bias input device and modulates an optical signal on the basis of a radio frequency signal from the radio frequency signal input device.

9. An optical modulation system according to claim 8, wherein the optical modulator is connected to the output via a transmission line.
